(19) United States
(12) Patent Application Publication
(10) Pub. No.: US 2026/0068718 A1
(43) Pub. Date: Mar. 5, 2026

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventor: Wooyeol Lee, Suwon-si (KR)

(21) Appl. No.: 19/233,137

(22) Filed: Jun. 10, 2025

(30) Foreign Application Priority Data
Aug. 27, 2024 (KR) 10-2024-0114699

(51) Int. Cl. H01L 23/498; H01L 21/48; H01L 23/00

(52) U.S. Cl. CPC H01L 23/49838

(57) ABSTRACT

A semiconductor package includes a package substrate having bond fingers, at least one semiconductor chip on the package substrate, the at least one semiconductor chip having chip pads on an upper surface thereof, and conductive wires electrically connecting the chip pads and the bond fingers, wherein the package substrate includes an insulating layer having an upper surface and a lower surface opposite the upper surface, the insulating layer having a recess of a predetermined depth from the upper surface of the insulating layer, upper circuit wirings having pad patterns in the insulating layer and extending such that at least a portion of each of the pad patterns is exposed from a bottom surface of the recess, and a respective plating pattern on the portion of each of the pad patterns that is exposed, the respective plating pattern provided as the bond finger.

### CROSS-REFERENCE TO RELATED APPLICATION

This application claims the benefit of priority under 35 U.S.C. § 119 to Korean Patent Application No. 10-2024-0114699, filed on Aug. 27, 2024 in the Korean Intellectual Property Office (KIPO), the disclosure of which is herein incorporated by reference in its entirety.

### BACKGROUND

Example embodiments relate generally to a semiconductor package and a method of manufacturing the semiconductor package, and more particularly relate to a semiconductor package including an embedded trace substrate (ETS) in which circuit patterns are embedded and a method of manufacturing the semiconductor package

In order to cope with a recent trend of miniaturization and thinning of electronic products, an embedded trace substrate (ETS) in which circuit patterns are embedded in an insulating layer has been used. An additional protruding pattern or protruding pad may be formed on the circuit pattern to electrically connect components mounted on the ETS to the circuit pattern. However, since the protruding pattern or the protruding pad is formed to have a pitch wider than a pitch of the circuit pattern in the process, the ETS may be required to have a finer pitch, to increase a density of the electronic product.

### SUMMARY

Example embodiments provide a semiconductor package having bond fingers of a fine pitch.

Example embodiments provide a method of manufacturing the semiconductor package.

According to example embodiments, a semiconductor package includes, a package substrate having a plurality of bond fingers, at least one semiconductor chip disposed on the package substrate, the at least one semiconductor chip having a plurality of chip pads on an upper surface thereof, and conductive wires electrically connecting the plurality of chip pads and the plurality of bond fingers. The package substrate includes an insulating layer having an upper surface and a lower surface opposite the upper surface, the insulating layer having a recess of a predetermined depth from the upper surface of the insulating layer, upper circuit wirings having a plurality of pad patterns embedded in the insulating layer and extending such that at least a portion of each of the pad patterns is exposed from a bottom surface of the recess, and a plating pattern on the exposed portion of each of the pad patterns, the plating pattern provided as the bond finger.

According to example embodiments, a semiconductor package includes, an insulating layer having an upper surface and a lower surface opposite the upper surface, the insulating layer having a recess of a predetermined depth from the upper surface, upper circuit wirings having a plurality of pad patterns embedded in the insulating layer and extending such that an upper surface and an upper side surface of each of the pad patterns are exposed from a bottom surface of the recess, a plating pattern disposed on the upper surfaces and the upper side surfaces of the plurality of pad patterns respectively, at least one semiconductor chip disposed on the upper surface of the insulating layer, the at least one semiconductor chip having a plurality of chip pads on an upper surface thereof, and conductive wires electrically connecting the plurality of chip pads to the plating patterns.

According to example embodiments, a semiconductor package includes, an upper insulating layer having an upper surface and a lower surface opposite the upper surface, the insulating layer having a recess of a predetermined depth from the upper surface, upper circuit wirings having a plurality of pad patterns embedded in the upper insulating layer and extending such that an upper surface and an upper side surface of each of the pad patterns are exposed from a bottom surface of the recess, plating patterns provided on the upper surfaces and the upper side surfaces of the plurality of pad patterns respectively, at least one lower insulating layer disposed on the lower surface of the upper insulating layer, at least one semiconductor chip disposed on the upper surface of the upper insulating layer, the at least one semiconductor chip having a plurality of chip pads on an upper surface thereof, and conductive wires electrically connecting the plurality of chip pads to the plating patterns.

According to example embodiments, in a method of manufacturing a semiconductor package, upper circuit wirings including a plurality of pad patterns are formed on a surface of a core layer. An insulating layer covering the upper circuit wirings is formed. Lower circuit wirings electrically connected to the upper circuit wirings are formed on a first surface of the insulating layer. The core layer is separated and removed from the insulating layer. A recess is formed in a second surface opposite to the first surface of the insulating layer to expose at least portions of the plurality of pad patterns. A metal plating process is performed to form plating patterns on the exposed portions of the plurality of pad patterns. At least one semiconductor chip is placed on the second surface of the insulating layer. Chip pads of the at least one semiconductor chip are electrically connected to the plating patterns using bonding wires.

In example embodiments, each of the at least portions of the plurality of pad patterns may include an upper surface and an upper side surface of each of the plurality of pad patterns.

In example embodiments, the method may further include forming a solder resist layer on the second surface of the insulating layer and exposing the recess.

In example embodiments, forming the plating patterns may include forming a first plating pattern on each of the exposed at least portions of the plurality of pad patterns; and forming a second plating pattern on the first plating pattern.

In example embodiments, the first plating pattern may include nickel, and the second plating pattern may include gold.

In example embodiments, forming the recess in the second surface of the insulating layer may include irradiating the second surface of the insulating layer with a laser beam to form the recess.

In example embodiments, a height of each of the plurality of pad patterns in a first direction perpendicular to the second surface of the insulating layer from a bottom of the recess may be 95% or less of a thickness of each of the plurality of pad patterns in the first direction.

According to example embodiments, an insulating layer may include a recess that extends from an upper surface thereof. A pad pattern may be embedded such that an upper side surface thereof is exposed from the recess. The plating pattern may cover an upper surface and the upper side surface of the pad pattern to serve as a bond finger for wire bonding.

Accordingly, a portion of a circuit pattern may be exposed through the recess and the bond finger may be formed on the exposed portion of the circuit pattern, and thus, the bond fingers may have a finer pitch compared to the existing semiconductor package having a protruding pad on which a bonding wire is bonded.

### BRIEF DESCRIPTION OF THE DRAWINGS

Example embodiments will be more clearly understood from the following detailed description taken in conjunction with the accompanying drawings. FIGS. 1 to 19 represent non-limiting, example embodiments as described herein wherein like reference numerals (when used) indicate corresponding elements throughout the several views.

FIGS. 1 to 3 are schematic views illustrating a semiconductor package in accordance with example embodiments.

FIGS. 4 to 18 are schematic views illustrating intermediate processes in a method of manufacturing a semiconductor package in accordance with example embodiments.

FIG. 19 is a schematic cross-sectional view illustrating a semiconductor package in accordance with example embodiments.

### DETAILED DESCRIPTION

Hereinafter, example embodiments will be explained in detail with reference to the accompanying drawings.

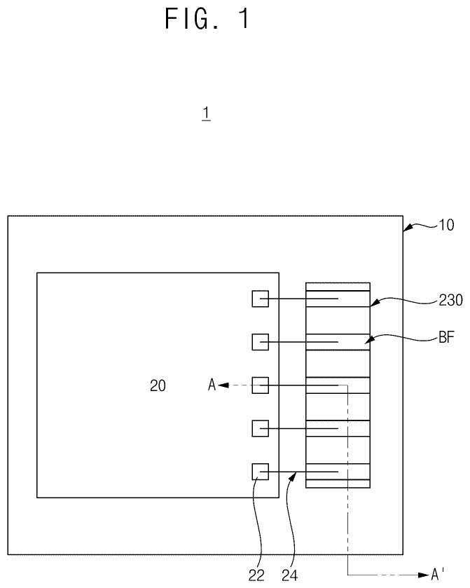

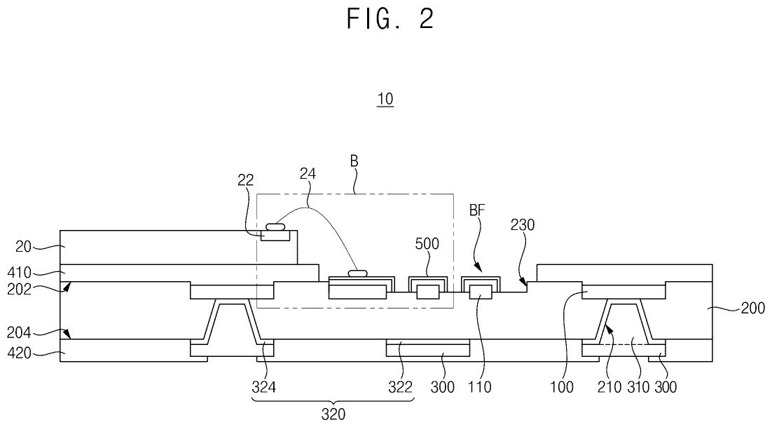

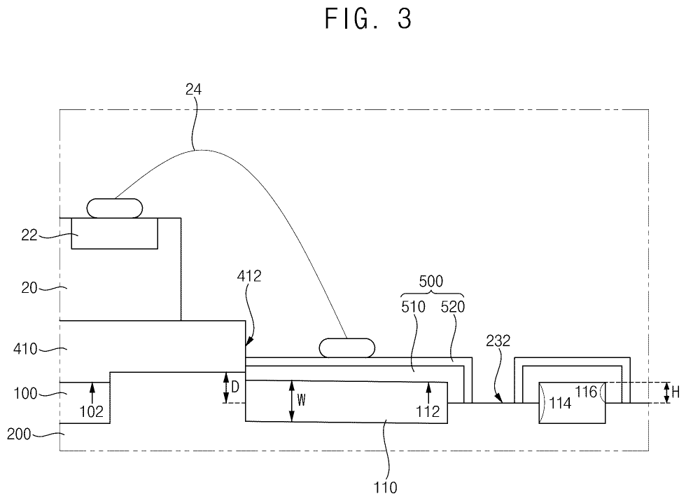

FIGS. 1 to 3 are schematic views illustrating a semiconductor package in accordance with example embodiments. FIG. 1 is a schematic plan view illustrating a semiconductor package in accordance with example embodiments. FIG. 2 is a schematic cross-sectional view taken along the line A-A′ line in FIG. 1. FIG. 3 is an enlarged schematic cross-sectional view illustrating a region ‘B’ in FIG. 2.

Referring to FIGS. 1 to 3, a semiconductor package 1 may include a package substrate 10, at least one semiconductor chip 20 disposed on the package substrate 10, and conductive wires 24 electrically connecting the package substrate 10 and the at least one semiconductor chip 20. The term “connecting” (or “connected,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

In example embodiments, the package substrate 10 may be a substrate having an upper surface 202 and a lower surface 204 opposite the upper surface 202. For example, the package substrate 10 may be a coreless substrate formed by an embedded trace substrate (ETS) method. The embedded trace substrate may include at least one insulating layer and circuit patterns embedded in the at least one insulating layer.

The at least one semiconductor chip 20 may be provided (e.g., mounted) on the upper surface 202 of the package substrate 10. Chip pads 22 may be disposed on the upper surface of the at least one semiconductor chip 20. As described later, the package substrate 10 may include pad patterns 110, and a plating pattern 500 on each of the pad patterns 110, which are provided as bond fingers BF exposed by a recess 230. The term “exposed” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The conductive wire 24 may electrically connect the chip pads 22 to the plating pattern 500 of the bond finger BF. The at least one semiconductor chip 20 may include a wire bonding chip.

Hereinafter, the package substrate will be described in detail.

Referring again to FIGS. 2 and 3, the package substrate 10 may include an insulating layer 200, upper circuit wirings 100 disposed on the upper surface 202 of the insulating layer 200, and lower circuit wirings 300 disposed on the lower surface 204 of the insulating layer 200. In addition, the package substrate 10 may further include a first solder resist layer 410 and a second solder resist layer 420 that respectively cover the upper surface 202 and the lower surface 204 of the insulating layer 200. The term “cover” (or “covering,” or like terms), as may be used herein, is intended to broadly refer to an element, structure or layer that is on or over another element, structure or layer, either directly or with one or more other intervening elements, structures or layers therebetween.

In example embodiments, the insulating layer 200 may have the recess 230 having a preset depth D in a vertical direction, perpendicular to the upper surface 202, from the upper surface 202. The preset depth D of the recess 230 may be a distance from a bottom surface 232 of the recess 230 to the upper surface 202 of the insulating layer 200. For example, the recess 230 may extend in a rectangular shape along one side of the insulating layer 200.

In example embodiments, the upper circuit wiring 100 may be disposed to be embedded in the upper surface 202 of the insulating layer 200. The upper circuit wiring 100 may be a pattern that extends in the insulating layer 200. An upper surface 102 of the upper circuit wiring 100 may be embedded to be coplanar with or lower than the upper surface 202 of the insulating layer 200.

The upper circuit wiring 100 may include a plurality of pad patterns 110 that extend in the recess 230 such that at least a portion of the pad pattern is exposed from the bottom surface 232 of the recess 230. The pad pattern 110 may be disposed such that an entire upper surface 112 and a portion of a side surface 114 are exposed within the recess 230. The side surface 114 of the pad pattern 110 may include an upper side surface 116 located higher than the bottom surface 232 of the recess 230. A distance from the upper surface 112 of the pad pattern 110 to the bottom surface 232 of the recess 230, i.e., a height H of the upper side surface 116 in the vertical direction may be within a range of about 95% of a thickness W of the pad pattern 110 or less. Alternatively, an entire side surface 114 of the pad pattern 110 may be exposed from the bottom surface 232 of the recess 230.

In example embodiments, the lower circuit wiring 300 may be disposed on the lower surface 204 of the insulating layer 200. The lower circuit wiring 300 may include a via electrode 310 that penetrates (i.e., extends in) the insulating layer 200, through a via hole 210 formed in the insulating layer 200, and is electrically connected to the upper circuit wiring 100, and a seed layer 320 interposed between the lower surface 204 of the insulating layer 200 and the lower circuit wiring 300.

The via electrode 310 may extend to at least partially penetrate the insulating layer 200 inside the insulating layer 200. The via electrode 310 may extend in the insulating layer 200 in a tapered shape having a width that increases toward the lower surface 204 of the insulating layer 200. The via electrode 310 may extend so that the lower surface forms a same plane as the lower surface 204 of the insulating layer 200. The via electrode 310 may be electrically connected to the upper circuit wirings 100. The via electrode 310 may include a same material as the upper circuit wiring 100. In this embodiment, the via electrode 310 is illustrated having the tapered shape, but is not limited thereto, and for example, the via electrode may have a cylindrical shape or a pillar shape.

The lower circuit wiring 300 may be a pattern that extends on the lower surface 204 of the insulating layer 200. The lower circuit wiring 300 may be disposed on the via electrode 310. For example, the lower circuit wiring 300 may be disposed on the lower surface 204 of the insulating layer 200 to cover the via electrode 310. Accordingly, the lower circuit wiring 300 may be electrically connected to the upper circuit wiring 100 through the via electrode 310.

The seed layer 320 may be disposed on the lower surface 204 of the insulating layer 200. The seed layer 320 may include a first seed layer 322 interposed between the lower circuit wiring 300 and the lower surface 204 of the insulating layer 200 and a second seed layer 324 interposed between the via electrode 310 and the insulating layer 200. The second seed layer 324 may be disposed along a profile consisting of an outer surface of the via electrode 310 inside the insulating layer 200 and a portion of the lower surface 204 of the insulating layer 200. For example, the first seed layer 322 and the second seed layer 324 may have a same thickness. The first seed layer 322 and the second seed layer 324 may include copper (Cu).

In example embodiments, the first solder resist layer 410 may be disposed on the upper surface 202 of the insulating layer 200. The second solder resist layer 420 may be disposed on the lower surface 204 of the insulating layer 200. The first solder resist layer 410 may expose the recess 230 on the upper surface 202 of the insulating layer 200. Accordingly, the first solder resist layer 410 may expose portions of the upper circuit wirings 100, that is, the pad patterns 110, on the upper surface 202 of the insulating layer 200. The second solder resist layer 420 may expose portions of the lower circuit wirings 300 on the lower surface 204 of the insulating layer. For example, the first solder resist layer 410 may have an exposure portion 412 exposing the recess 230. The second solder resist layer 420 may expose a portion of the second lower circuit wiring 300. The first and second solder resist layers 410 and 420 may include a material such as a photo solder resist (PSR) or an epoxy resin, although embodiments are not limited thereto.

In example embodiments, the plating pattern 500 may cover an exposed portion of the pad pattern 110. The plating pattern 500 may cover the upper surface 112 and the upper side surface 116 of the pad pattern 110 to completely cover the exposed portion of the pad pattern 110. Alternatively, when the entire side surface 114 of the pad pattern 110 is exposed from the bottom surface 232 of the recess 230, the plating pattern 500 may cover the upper surface 112 and the side surface 114 of the pad pattern 110. The plating pattern 500 may include a first metal pattern 510 and a second metal pattern 520.

The first metal pattern 510 may be disposed to cover the upper surface 112 and the upper side surface 116 of the pad pattern 110. For example, the exposed portion of the pad pattern 110 may have a rectangular cross section. Since the first metal pattern 510 may be formed along a profile of the exposed portion of the pad pattern 110, the first metal pattern 510 may have a rectangular cross section having an upper surface and a side surface. The second metal pattern 520 may be disposed to cover the first metal pattern 510. Since the second metal pattern 520 may be disposed along a profile of the first metal pattern 510, the second metal pattern 520 may similarly have a rectangular cross section having an upper surface and a side surface. The first metal pattern 510 may include nickel (Ni) or aluminum (Al). The second metal pattern 520 may include gold (Au). The pad pattern 110 and the plating pattern 500 formed on the upper circuit wirings 100 may serve as the bond finger that provides a plane to which a bonding wire is bonded.

As mentioned above, the semiconductor package 1 may include the package substrate 10, the at least one semiconductor chip 20 disposed on the package substrate 10, and the conductive wires 24 electrically connecting the package substrate 10 and the at least one semiconductor chip 20. The package substrate 10 may include the insulating layer 200, the upper circuit wirings 100 disposed on the upper surface 202 of the insulating layer 200 and having the pad patterns 110 of which at least a portion is exposed from the bottom surface of the recess 230, the lower circuit wirings 300 disposed on the lower surface 204 of the insulating layer 200, and the plating pattern 500 covering the exposed portion of each of the pad patterns 110 of the upper circuit wiring 100.

The insulating layer 200 may include the recess 230 extending from the upper surface 202. The pad pattern 110 may be embedded such that the upper side surface 116 is exposed from the recess 230. The plating pattern 500 may cover the upper surface 112 and the upper side surface 116 of the pad pattern 110 to serve as the bond finger for wire bonding.

Accordingly, the semiconductor package according to example embodiments may expose a portion of a circuit pattern through the recess 230, may provide the bond finger on the exposed circuit pattern, and may include the bond fingers having a finer pitch compared to the existing semiconductor package having a protruding pad on which a bonding wire is bonded.

Further, the package substrate 10 according to the example embodiments may include the embedded circuit wiring having a recess depth from the upper surface of the package substrate and a protruding circuit pattern protruding from the upper surface of the package substrate, thereby having advantages of simultaneously mounting a flip chip and a wire bonding chip on the package substrate.

Hereinafter, a method of manufacturing the semiconductor package in FIG. 1 will be described.

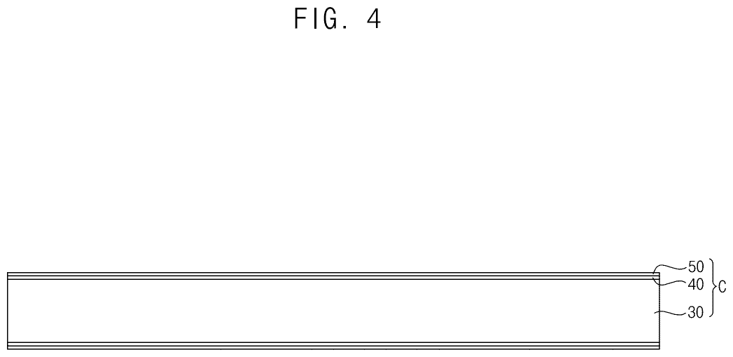

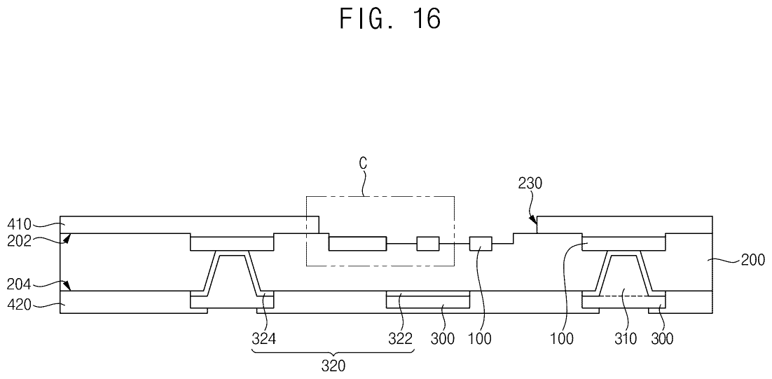

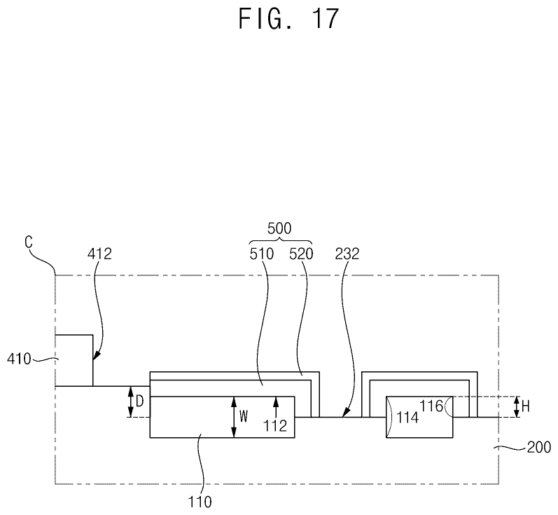

FIGS. 4 to 18 are schematic cross-sectional views illustrating intermediate processes in the method of manufacturing a semiconductor package in accordance with example embodiments. FIG. 17 is an enlarged schematic cross-sectional view illustrating region ‘C’ in FIG. 16.

Referring to FIG. 4, first, a carrier substrate C may be prepared. The carrier substrate C may include a core layer 30, an inner metal layer 40 formed on both (opposing) surfaces of the core layer 30, and an outer metal layer 50 formed on the inner metal layer 40. Each of the inner metal layer 40 and the outer metal layer 50 may be a Cu foil, but is not limited thereto.

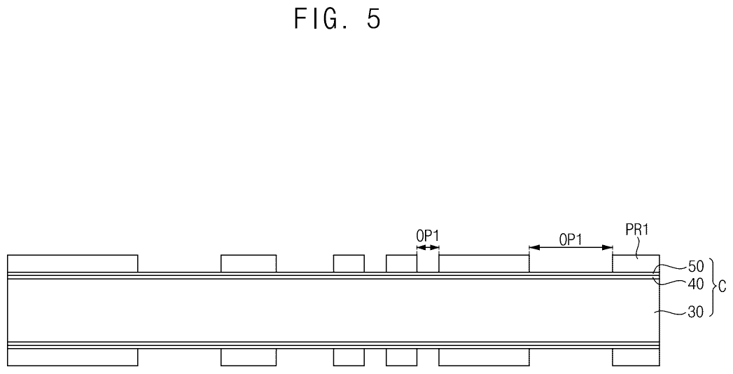

Referring to FIGS. 5 to 7, an upper circuit wiring 100 may be formed on the outer metal layer 50 on the carrier substrate C.

First, as illustrated in FIG. 5, a first photoresist pattern PR1 for forming the upper circuit wiring 100 may be formed on the outer metal layer 50. For example, a first photoresist layer may be formed on the outer metal layer 50, and the first photoresist layer may be patterned to form the first photoresist pattern PR1 having first openings OP1 that expose portions of the outer metal layer 50. The first photoresist layer may include a photosensitive material. The photosensitive material may include a dry film, a photoresist, a photo solder resist, etc.

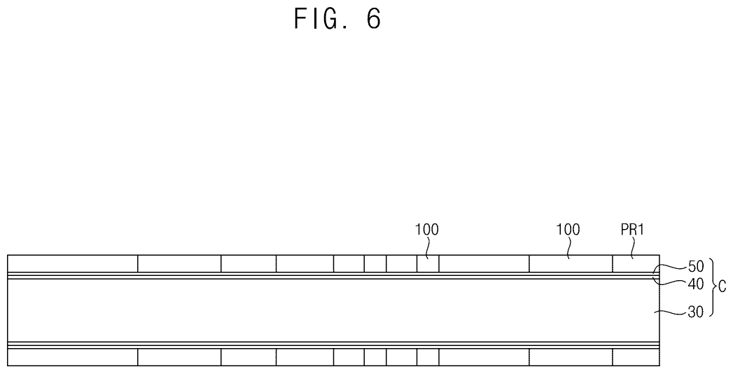

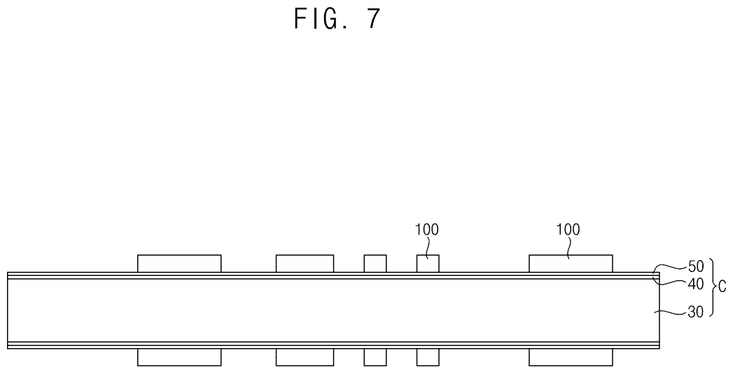

As illustrated in FIGS. 6 and 7, the first openings OP1 of the first photoresist pattern PR1 may be filled up with a conductive metal to form the upper circuit wiring 100. The term “filled” (or “fills,” or like terms) is intended to refer to either completely filling a defined space (e.g., the first openings OP1) or partially filling the defined space; that is, the defined space need not be entirely filled but may, for example, be partially filled or have voids or other spaces throughout. The first openings OP1 may be filled up with the conductive metal by performing a process such as electroplating, but is not limited thereto. The conductive metal may include, for example, copper (Cu). Then, the first photoresist pattern PR1 may be removed from the carrier substrate.

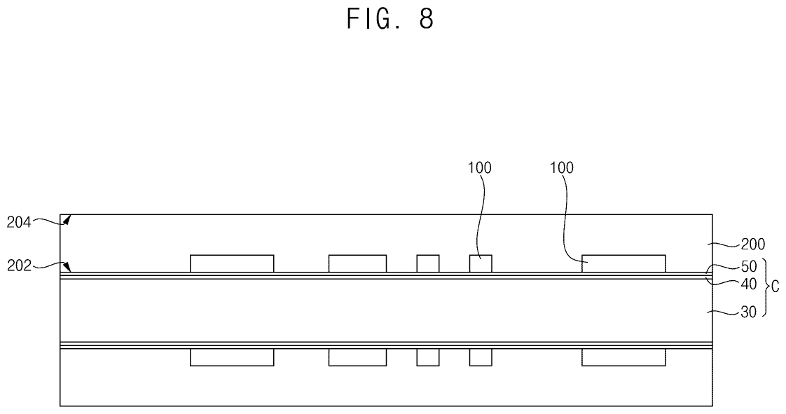

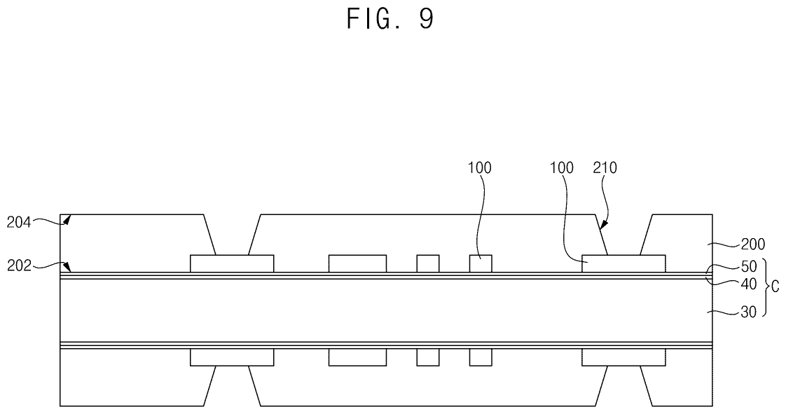

Referring to FIGS. 8 and 9, an insulating layer 200 having a plurality of via holes 210 therein may be formed.

As illustrated in FIG. 8, the insulating layer 200 may be formed on the outer metal layer 50 of the core layer 30 to cover the upper circuit wiring 100.

Then, as illustrated in FIG. 9, the via holes 210 may be formed in the insulating layer 200 to expose the portions of the upper circuit wiring 100. The via hole 210 may be formed to at least partially penetrate the insulating layer 200. In example embodiments, the via hole 210 may be formed in the insulating layer 200 in a tapered shape having a width, in a horizontal direction parallel to a surface of the insulating layer 200, that increases gradually from the exposed portion of the upper circuit wiring 100 toward a lower surface 204 of the insulating layer 200. A lower portion of the via hole 210 may be formed to have a width less than a width of the upper circuit wiring 100, to expose the portion of the upper circuit wiring. In this embodiment, the via hole is illustrated having the tapered shape, but is not limited thereto, and for example, the via hole may have a cylindrical shape or a pillar shape.

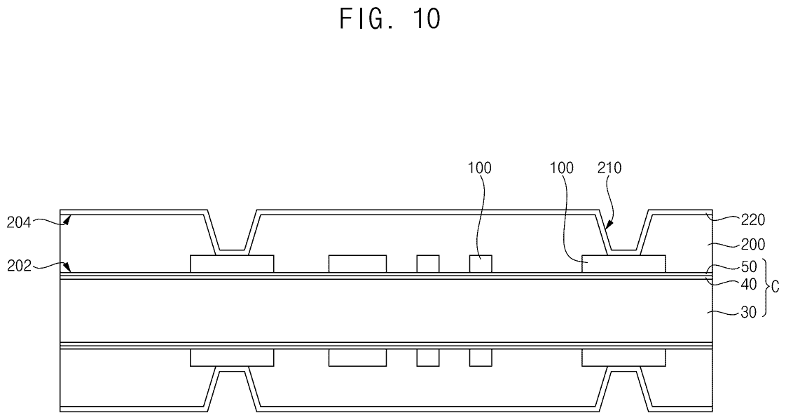

Referring to FIGS. 10 to 13, a seed layer 220 and a lower circuit wiring 300 including a plurality of via electrodes 310 may be formed on the insulating layer 200.

As illustrated in FIG. 10, the seed layer 220 may be formed on the insulating layer 200. The seed layer 220 may be formed to cover an upper surface 202 of the insulating layer 200, inner surfaces of the plurality of via holes 210, and the upper circuit wiring 100 exposed by the plurality of via holes. That is, the seed layer 220 may be formed along a profile of the upper surface 202 of the insulating layer 200, the inner surfaces of the via holes 210, and the upper circuit wiring 100 exposed by the via holes 210. The seed layer may be formed by performing an electroless plating process, but is not limited thereto. The seed layer may include copper (Cu).

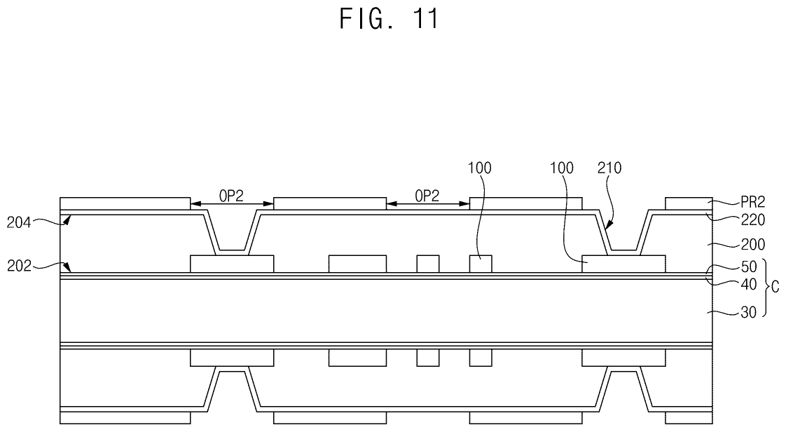

As illustrated in FIG. 11, a second photoresist pattern PR2 may be formed on the seed layer 220 on the insulating layer 200. First, a second photoresist layer may be formed on the seed layer 220 on the insulating layer 200, and the second photoresist layer may be patterned to form the second photoresist pattern PR2 having second openings OP2 that expose portions of the seed layer 220. The second openings OP2 may expose a portion of the seed layer 220 formed on the insulating layer 200 and a portion of the seed layer 220 formed on the inner surface of the via hole 210. The second photoresist layer may include a photosensitive material. The photosensitive material may include a dry film, a photoresist, a photo solder resist, etc.

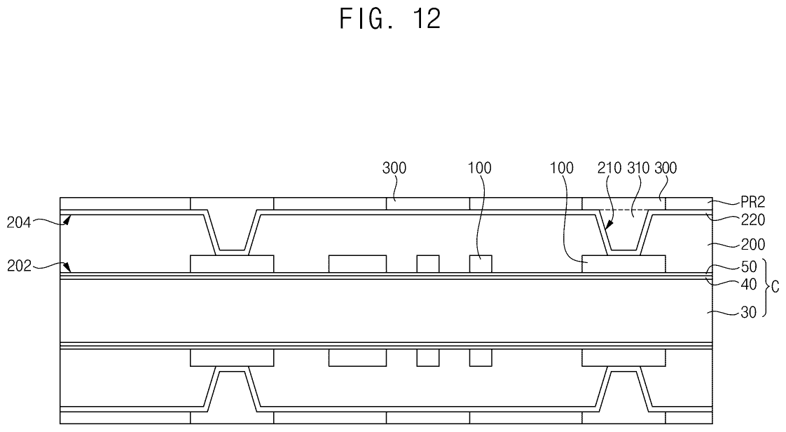

As illustrated in FIG. 12, the second openings OP2 of the second photoresist pattern PR2 may be filled up with conductive metal to form the plurality of via electrodes 310 and the lower circuit wiring 300. For example, the second openings exposing the portion of the seed layer 220 formed on the via hole 210 may be filled up with a conductive metal to form the via electrode 310, and the second openings exposing the portion of the seed layer 220 formed on the insulating layer 200 may be filled up with a conductive metal to form the lower circuit wiring 300. The filling of the second openings with the conductive metal may be performed by a process such as electroplating, but is not limited thereto. The conductive metal may include, for example, copper (Cu).

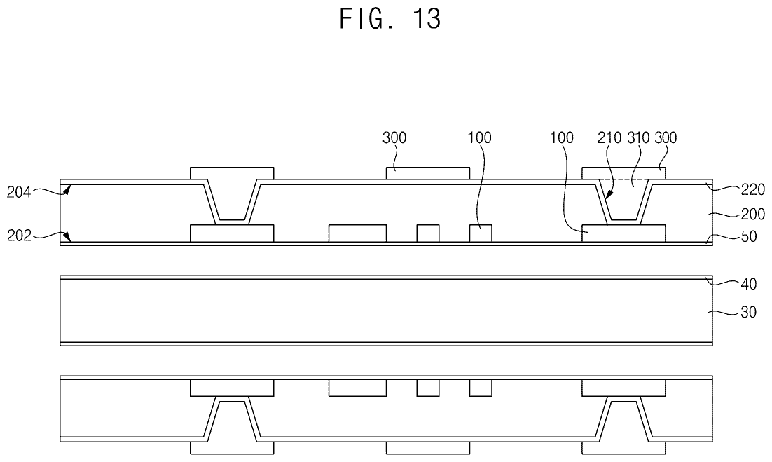

Referring to FIG. 13, the second photoresist pattern PR2 may be removed, and the insulating layer 200 may be separated from the core layer 30. In particular, the inner metal layer 40 and the outer metal layer 50 of the core layer 30 may be peeled off from the insulating layer 200. A blade may be used to peel the inner metal layer and the outer metal layer, but is not limited thereto.

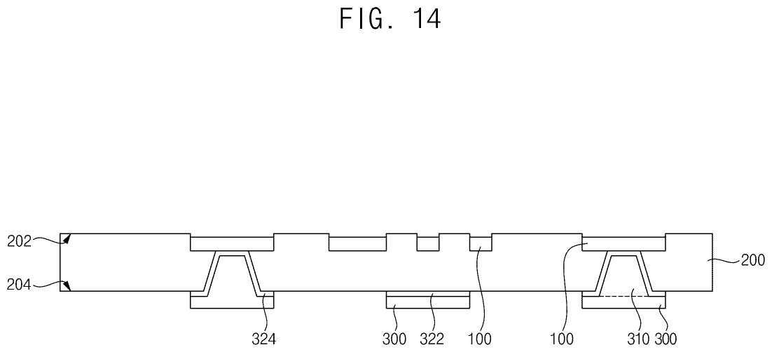

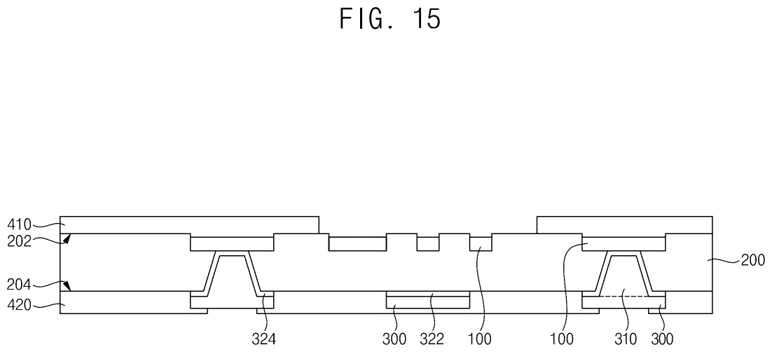

Referring to FIGS. 14 and 15, an etching process may be performed on the separated insulating layer 200 to remove portions of the seed layer 220 (see FIG. 13), and then, first and second solder resist layers 410 and 420 may be formed on an upper surface 202 and a lower surface 204 of the insulating layer 200, respectively.

As illustrated in FIG. 14, the seed layer 220 on the lower surface 204 of the insulating layer 200 and the outer metal layer 50 on the upper surface 202 of the insulating layer 200 may be etched. The seed layer 220 may be etched to form a first seed layer 322 interposed between the lower circuit wiring 300 and the insulating layer 200, and a second seed layer 324 interposed between the via electrode 310 and the via hole 210 may be formed. When the outer metal layer 50 (see FIG. 13) is etched on the upper surface 202 of the insulating layer, a portion of the upper circuit wiring 100 may be etched together.

As illustrated in FIG. 15, the first solder resist layer 410 may be formed on the upper surface 202 of the insulating layer 200, and the second solder resist layer 420 may be formed on the lower surface 204 of the insulating layer 200.

The first solder resist layer 410 may be formed to expose a recess region on the upper surface 202 of the insulating layer 200. For example, an upper solder resist layer may be formed on the upper surface 202 of the insulating layer 200, and the upper solder resist layer may be selectively patterned to form an exposure portion 412 (see FIG. 17) exposing the recess region.

The second solder resist layer 420 may be formed to expose a portion of the lower circuit wirings 300 on the lower surface 204 of the insulating layer 200. The second solder resist layer 420 may include a material such as a photo solder resist (PSR) or an epoxy resin.

Referring to FIGS. 16 and 17, a recess 230 may be formed in the upper surface 202 of the insulating layer 200 to expose a portion of the upper circuit wiring 100, and a plating pattern 500 may be formed on the exposed portion of the upper circuit wiring 100.

As illustrated in FIG. 16, the recess 230 may be formed in the upper surface 202 of the insulating layer 200. In example embodiments, a laser may be irradiated onto the upper surface 202 of the insulating layer 200 to remove a portion of the upper surface 202 of the insulating layer 200 until the portion of the upper circuit wiring 100 is exposed. The upper circuit wiring exposed by the recess 230 may be a pad pattern 110. Since the pad pattern 110 may include a metal, the pad pattern 110 may reflect a laser so as to be processed such that only the upper surface of the insulating layer 200 except the pad pattern 110 is removed. For example, the recess 230 may be formed to have a quadrangular shape along one side of the insulating layer 200.

The recess 230 may have a bottom surface 232 that extends on the upper surface 202 of the insulating layer 200 to have a preset depth D from the upper surface 202. Accordingly, an upper surface 112 and an upper side surface 116 of the pad pattern 110 may be exposed from the bottom surface 232 of the recess. A distance from the upper surface 112 of the exposed pad pattern to the bottom surface 232 of the recess 230, i.e., a height H, in the vertical direction, of the upper side surface 116 may be within a range equal to or less than 95% of a thickness W, in the horizontal direction, of a side surface 114 of the upper circuit wiring 100. Alternatively, the recess 230 may be formed such that the entire side surface 114 of the pad pattern 110 is exposed.

Then, as illustrated in FIG. 17, the plating pattern 500 may be formed on the pad pattern 110. In example embodiments, the plating pattern 500 may be disposed to cover the exposed portion of the pad pattern 110. The plating pattern 500 may be formed on the upper surface 202 of the insulating layer 200 to cover the upper surface 112 and the upper side surface 116 of the pad pattern 110 to completely cover the exposed portion of the pad pattern 110. Alternatively, when the entire side surface 114 of the pad pattern 110 is exposed from the bottom surface 232 of the recess 230, the plating pattern 500 may be formed to cover the upper surface 112 and the side surface 114 of the pad pattern 110. The plating pattern 500 may include a first metal pattern 510 and a second metal pattern 520 stacked on the first metal pattern 510.

The first metal pattern 510 may be formed to cover the upper surface 112 and the upper side surface 116 of the pad pattern 110. Since the first metal pattern 510 may be disposed along a profile of the upper surface 112 and the upper side surface 116 of the pad pattern 110, the first metal pattern may have a rectangular cross section having an upper surface and a side surface. The second metal pattern 520 may be disposed to cover the first metal pattern 510. Since the second metal pattern 520 may be disposed along a profile of the first metal pattern 510, the second metal pattern 520 may have a rectangular cross section having an upper surface and a side surface. The first metal pattern 510 may include nickel (Ni) or aluminum (Al). The second metal pattern 520 may include gold (Au). The pad pattern 110 and the plating pattern 500 formed on the pad pattern 110 may serve as a bond finger which may provide a plane to which the bonding wire is bonded.

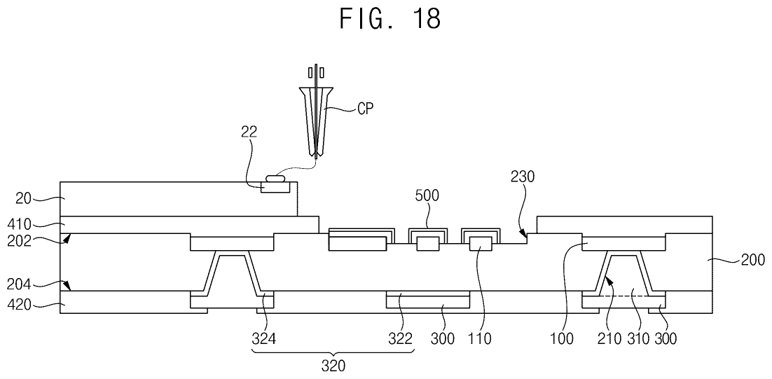

Referring to FIG. 18, at least one semiconductor chip 20 may be mounted on the package substrate 10 using conductive wires 24, thereby completing the semiconductor package 1 of FIG. 1.

As illustrated in FIG. 18, the at least one semiconductor chip 20 may be disposed on the first solder resist layer 410. The at least one semiconductor chip 20 may be a chip for wire bonding. The at least one semiconductor chip 20 may include a plurality of chip pads 22 on an upper surface thereof. A capillary CP providing a conductive member, which is a material of the conductive wire 24 (see FIG. 2), may be located over the chip pads 22 or the bond finger BF and the conductive member may be drawn such that the conductive wire 24 may extend from the chip pad 22 of the at least one semiconductor chip 20 to the bond finger BF to electrically connect the at least one semiconductor chip 20 to the package substrate 10. The conductive wire 24 may include at least one of copper (Cu), aluminum (Al), tungsten (tungsten), nickel (Ni), molybdenum (Mo), gold (Au), silver (Ag), chromium (Cr), tin (Sn), or titanium (Ti).

According to example embodiments, unlike a related art in which wire bonding process is performed on a protruding pad, a recess may be formed by performing laser processing to expose a portion of a circuit pattern and a bond finger may be formed on the exposed circuit pattern. Accordingly, the bond fingers with a pitch finer than the related art may be provided. Furthermore, in the related art, a plated metal is formed in a rounded shape to provide a bond finger with a rounded plane, whereas the package substrate according to example embodiments has the advantage of providing a bond finger with excellent wire bonding strength by having a flat upper surface compared to the related art.

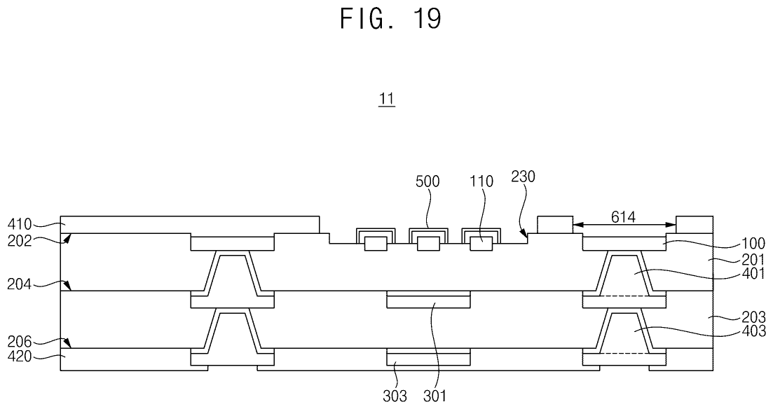

FIG. 19 is a schematic cross-sectional view illustrating a package substrate according to one or more embodiments. The package substrate is substantially the same as the package substrate of the semiconductor package described with reference to FIG. 2, except that the package substrate includes at least one lower insulating layer on a lower surface of the insulating layer. Accordingly, same reference numerals will be used to refer to the same or like elements and any further repetitive explanation concerning the above elements will be omitted.

Referring to FIG. 19, a package substrate 11 may include an upper insulating layer 201, a lower insulating layer 203, an upper circuit wiring 100 disposed on an upper surface 202 of the upper insulating layer 201 and having pad patterns 110, a lower circuit wiring 300 disposed on a lower surface 204 of the lower insulating layer 203, and a plating pattern 500 covering each of the pad patterns 110 of the upper circuit wiring 100. Additionally, the package substrate 11 may further include a solder resist layer 410 disposed on the upper insulating layer 201.

In this embodiment, a semiconductor package is illustrated having two insulating layers stacked on each other, but the number of insulating layers to be stacked is not limited thereto, and two or more insulating layers may be stacked.

In example embodiments, the upper insulating layer 201 may have an upper surface 202 and a lower surface 204 opposite the upper surface 202. First via electrodes 401 may extend within the upper insulating layer 201. The first via electrodes 401 may be electrically connected to the upper circuit wiring 100 disposed on the upper surface 202 of the upper insulating layer 201. The lower circuit wiring 300 may be disposed on the lower surface 204 of the upper insulating layer 201.

In example embodiments, the lower insulating layer 203 may be stacked on the lower surface 204 of the upper insulating layer 201. The lower insulating layer 203 may be disposed to cover a first lower circuit wiring 301 exposed on the lower surface 204 of the upper insulating layer 201. Second via electrodes 403 may extend within the lower insulating layer 203. The second via electrodes 403 may be electrically connected to the upper circuit wiring 100 through the first lower circuit wiring 301 disposed on the lower surface 204 of the upper insulating layer 201 and the first via electrodes 401.

In example embodiments, the lower insulating layer 203 may have a second lower circuit wiring 303 on a lower surface 206 thereof. The second lower circuit wiring 303 may be a pattern disposed on the lower surface 206 of the lower insulating layer 203. The second lower circuit wiring 303 may be disposed on the second via electrode 403. For example, the second lower circuit wiring 303 may be disposed to cover the second via electrode 403 on the lower surface 206 of the lower insulating layer 203. Accordingly, the second lower circuit wiring 303 may be electrically connected to the upper circuit wiring 100 through the first and second via electrodes 401 and 403.

In example embodiments, a first solder resist layer 410 may expose a recess 230 on the upper surface 202 of the upper insulating layer 201. Accordingly, the first solder resist layer 410 may expose a portion of the upper circuit wirings 100 on the upper surface 202 of the upper insulating layer 201. Likewise, a second solder resist layer 420 may expose a portion of the second lower circuit wiring 303 on the lower surface 206 of the lower insulating layer 203. The first and second solder resist layers 410 and 420 may include a material such as a photo solder resist (PSR) or an epoxy resin.

The foregoing is illustrative of example embodiments and is not to be construed as limiting thereof. Although a few example embodiments have been described, those skilled in the art will readily appreciate that many modifications are possible in some example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate having a plurality of bond fingers;
at least one semiconductor chip on the package substrate, the at least one semiconductor chip having a plurality of chip pads on an upper surface thereof; and
conductive wires electrically connecting the plurality of chip pads and the plurality of bond fingers,
wherein the package substrate includes:
an insulating layer having an upper surface and a lower surface opposite the upper surface, the insulating layer having a recess of a predetermined depth from the upper surface of the insulating layer in a first direction perpendicular to the upper surface of the insulating layer;
upper circuit wirings having a plurality of pad patterns in the insulating layer and extending such that at least a portion of each of the pad patterns is exposed from a bottom surface of the recess; and
a respective plating pattern on the at least a portion of each of the pad patterns that is exposed, the respective plating pattern provided as the bond finger.

2. The semiconductor package of claim 1, wherein an upper surface and an upper side surface of each of the pad patterns are exposed from the bottom surface of the recess.

3. The semiconductor package of claim 1, wherein a height, in the first direction, of each pad pattern from the bottom surface of the recess is equal to or less than a depth of the recess in the first direction.

4. The semiconductor package of claim 1, further comprising:
a solder resist layer on the upper surface of the insulating layer and exposing the recess.

5. The semiconductor package of claim 1, further comprising:
a plurality of lower circuit wirings on the lower surface of the insulating layer.

6. The semiconductor package of claim 1, wherein the respective plating pattern comprises:
a first plating pattern on the at least a portion of each of the pad patterns that is exposed; and
a second plating pattern on the first plating pattern.

7. The semiconductor package of claim 6, wherein the first plating pattern includes nickel, and the second plating pattern includes gold.

8. The semiconductor package of claim 1, wherein a height in the first direction of each pad pattern from the bottom surface of the recess is 95% or less of a thickness of the pad pattern in the first direction.

9. The semiconductor package of claim 1, further comprising:
at least one lower insulating layer on the lower surface of the insulating layer.

10. The semiconductor package of claim 9, wherein the insulating layer and the at least one lower insulating layer further include a plurality of lower circuit wirings on respective lower surfaces thereof.

11. A semiconductor package, comprising:
an insulating layer having an upper surface and a lower surface opposite the upper surface, the insulating layer having a recess of a predetermined depth from the upper surface in a first direction perpendicular to a surface of the insulating layer;
upper circuit wirings having a plurality of pad patterns in the insulating layer and extending such that an upper surface and an upper side surface of each of the plurality of pad patterns are exposed from a bottom surface of the recess;
plating patterns on the upper surfaces and the upper side surfaces of the plurality of pad patterns respectively;
at least one semiconductor chip on the upper surface of the insulating layer, the at least one semiconductor chip having a plurality of chip pads on an upper surface thereof; and
conductive wires electrically connecting the plurality of chip pads to the plating patterns.

12. The semiconductor package of claim 11, wherein a height in the first direction of each of the plurality of pad patterns from the bottom surface of the recess is equal to or less than a depth of the recess in the first direction.

13. The semiconductor package of claim 11, further comprising:
a solder resist layer on the upper surface of the insulating layer and exposing the recess.

14. The semiconductor package of claim 11, further comprising:
a plurality of lower circuit wirings on the lower surface of the insulating layer.

15. The semiconductor package of claim 11, wherein each of the plating patterns comprises:
a first plating pattern on the upper surface and the upper side surface of each of the plurality of pad patterns; and
a second plating pattern on the first plating pattern.

16. The semiconductor package of claim 15, wherein the first plating pattern includes nickel, and the second plating pattern includes gold.

17. The semiconductor package of claim 11, wherein a height in the first direction of each of the plurality of pad patterns from the bottom surface of the recess is 95% or less of a thickness of the each of the plurality of pad patterns in the first direction.

18. The semiconductor package of claim 11, further comprising:
at least one lower insulating layer on the lower surface of the insulating layer.

19. The semiconductor package of claim 18, wherein the insulating layer and the at least one lower insulating layer further include a plurality of lower circuit wirings on respective lower surfaces thereof.

20. A semiconductor package, comprising:
an upper insulating layer having an upper surface and a lower surface opposite the upper surface, the upper insulating layer having a recess of a predetermined depth from the upper surface in a first direction perpendicular to the lower surface of the upper insulating layer;
upper circuit wirings having a plurality of pad patterns in the upper insulating layer and extending such that an upper surface and an upper side surface of each of the plurality of pad patterns are exposed from a bottom surface of the recess;
plating patterns on the upper surfaces and the upper side surfaces of the plurality of pad patterns respectively;
at least one lower insulating layer on the lower surface of the upper insulating layer;
at least one semiconductor chip on the upper surface of the upper insulating layer, the at least one semiconductor chip having a plurality of chip pads on an upper surface thereof; and
conductive wires electrically connecting the plurality of chip pads to the plating patterns.
